(19) United States
(12) Patent Application Publication
(10) Pub. No.: US 2025/0334885 A1
(43) Pub. Date: Oct. 30, 2025

(54) LIGHT SOURCE APPARATUS

(71) Applicant: Lasertec Corporation, Yokohama (JP)

(72) Inventors: Masaki INOUE, Yokohama (JP); Masayasu NISHIZAWA, Yokohama (JP); Takayuki ISHIDA, Yokohama (JP); Takahide TAKAMATSU, Yokohama (JP); Junya KAWAGUCHI, Yokohama (JP)

(21) Appl. No.: 19/184,793

(22) Filed: Apr. 21, 2025

(30) Foreign Application Priority Data
Apr. 30, 2024 (JP) 2024-074000

(51) Int. Cl. G03F 7/00; H01J 65/04

(52) U.S. Cl. CPC G03F 7/70033; G03F 7/70916; H01J 65/042

(57) ABSTRACT

A light source apparatus according to the present disclosure includes: a target holding unit that has a holding surface for transporting a target material for generating plasma, to at least one plasma formation position; and a drive unit that drives the target holding unit, and moves the holding surface, wherein the holding surface moves with respect to a treatment surface in a space along the holding surface, the treatment surface includes: at least one plasma formation position; at least one supply position at which the target material is supplied to the holding surface; and at least one observation position at which state information on the target material held on the holding surface, the plasma formation position, the supply position, and the observation position are disposed along the treatment surface, and the treatment surface includes the supply position disposed after the plasma formation position.

### INCORPORATION BY REFERENCE

This application is based upon and claims the benefit of priority from Japanese patent application No. 2024-074000, filed on Apr. 30, 2024, the disclosure of which is incorporated herein in its entirety by reference for all purposes.

### BACKGROUND

The present disclosure relates to a light source apparatus.

Japanese Unexamined Patent Application Publication No. 2020-077007 describes a light source apparatus in which a target material is formed on a surface of a cylindrical member rotating around a rotational axis and which irradiates the formed target material with excitation light, thereby extracting illumination light.

Japanese Unexamined Patent Application Publication No. 2022-168463 describes a light source apparatus that holds, by a centrifugal force, a target material made of molten metal on the inner wall of a crucible rotating around a rotational axis, and irradiates the held target material with excitation light, thereby extracting illumination light.

### SUMMARY

In the light source apparatus, vibrations caused during rotation of the cylindrical member and the target holding unit, such as a crucible, the deformation of the structural object itself, the deformation due to the rotational stress and heat of the target holding unit itself, and putting of the target material to the target holding unit sometimes change the relative positions of a light emission point positioned around the surface of the target material and the optical member. A case is conceivable where this prevents light from being stably extracted from the light source apparatus.

The present disclosure has been made to solve such a problem, and has an object to provide a light source apparatus that can improve the stability of light to be extracted.

A light source apparatus according to the present disclosure includes: a target holding unit that has a holding surface for transporting a target material for generating plasma, to at least one plasma formation position; and a drive unit that drives the target holding unit, and moves the holding surface, wherein the holding surface moves with respect to a treatment surface in a space along the holding surface, the treatment surface includes: the at least one plasma formation position; at least one supply position at which the target material is supplied to the holding surface; and at least one observation position at which state information on the holding surface is acquired, the plasma formation position, the supply position, and the observation position are disposed along the treatment surface, and in the direction of movement of the holding surface driven by the drive unit, the treatment surface includes the supply position disposed after the plasma formation position, and further includes the observation position disposed after the supply position.

A light source apparatus according to the present disclosure includes: a target holding unit that has a holding surface for transporting a target material for generating plasma, to at least one plasma formation position; and a drive unit that drives the target holding unit, and moves the holding surface, wherein the holding surface moves with respect to a treatment surface in a space along the holding surface, the treatment surface includes: the at least one plasma formation position; and at least one supply position at which the target material is supplied to the holding surface, the plasma formation position and the supply position are disposed along the treatment surface, and in the direction of movement of the holding surface driven by the drive unit, a length from the plasma formation position to the supply position along the treatment surface is shorter than a length from the supply position to the plasma formation position along the treatment surface.

The light source apparatus may further include a formation unit that excites the target material at the plasma formation position by focusing laser light on the target material.

In the light source apparatus, the target holding unit may have a rotational axis, and the drive unit may transport the target material to the target holding unit by rotating the target holding unit around the rotational axis.

In the light source apparatus, the rotational axis may be substantially orthogonal to a contact surface.

In the light source apparatus, the treatment surface further may include at least one observation position at which state information on the holding surface is acquired, and the plasma formation position, the supply position, and the observation position may be disposed along the treatment surface.

In the light source apparatus, in the direction of movement of the holding surface driven by the drive unit, a length from the supply position to the observation position along the treatment surface may be shorter than a length from the observation position to the plasma formation position along the treatment surface.

The light source apparatus may further include a first debris shield disposed in a region between the plasma formation position and the supply position.

The light source apparatus may further include a second debris shield disposed in a region between the supply position and the observation position.

The light source apparatus may further include a third debris shield disposed in a region between the plasma formation position and the observation position.

The light source apparatus may further include a first debris shield, a second debris shield, and a third debris shield that are respectively disposed in a first region between the plasma formation position and the supply position, a second region between the supply position and the observation position, and a third region between the plasma formation position and the observation position.

The light source apparatus may further include a plurality of first debris shields, a plurality of second debris shields, and a plurality of third debris shields that are respectively disposed in a first region between the plasma formation position and the supply position, a second region between the supply position and the observation position, and a third region between the plasma formation position and the observation position.

In the light source apparatus, the first debris shield may include an elongated portion where a distance from the movement trajectory of the holding surface decreases in the movement direction.

In the light source apparatus, an angle between a portion that includes an end part of at least any of the first debris shield, the second debris shield, and the third debris shield on a side in the movement direction, and a tangent of the movement trajectory of the holding surface on an extended line of the end part may be less than 90°.

In the light source apparatus, a portion that includes the end part may include an elongated portion where a distance from the movement trajectory of the holding surface decreases in the movement direction, and has a convex shape on a side closer to the holding surface, to reduce an angle from the tangent of the movement trajectory of the holding surface on the extended line of the end part as approaching the end part.

In the light source apparatus, the second debris shield may include a portion disposed on a line extending from the rotational axis of the target holding unit to the treatment surface.

In the light source apparatus, at least any of the first debris shield, the second debris shield, and the third debris shield may be attached to a debris cover that covers the target holding unit.

In the light source apparatus, at least any of the first debris shield, the second debris shield, and the third debris shield may be adjusted to have a melting point higher than or equal to that of the target material.

In the light source apparatus, the plasma formation position may be disposed at a position that faces the observation position with respect to the rotational axis of the target holding unit.

The present disclosure can provide a light source apparatus that can improve the stability of light to be extracted.

The above and other objects, features and advantages of the present disclosure will become more fully understood from the detailed description given hereinbelow and the accompanying drawings.

### BRIEF DESCRIPTION OF DRAWINGS

FIG. 1 is a sectional view showing an example of a light source apparatus according to a first embodiment, and shows a section taken along line I-I of FIG. 2;

FIG. 2 is a sectional view showing an example of a light source apparatus according to the first embodiment, and shows a section taken along line II-II of FIG. 1;

FIG. 3 is a schematic diagram showing an example of an internal space of a target holding unit in a light source apparatus 1 according to the first embodiment;

FIG. 4 is a sectional view showing an example of a light source apparatus according to a second embodiment, and shows a section taken along line IV-IV of FIG. 5;

FIG. 5 is a sectional view showing an example of a light source apparatus according to the second embodiment, and shows a section taken along line V-V of FIG. 4; and

FIG. 6 is a sectional view showing an example of a light source apparatus according to a modification example of the second embodiment.

### DESCRIPTION OF EMBODIMENTS

A specific configuration of the present embodiment is described below with reference to the drawings. The following description indicates preferred embodiments of the present disclosure. The scope of the present disclosure is not limited to the following embodiments. In the following description, what is assigned the same symbol indicates similar content.

### First Embodiment

A light source apparatus according to a first embodiment is described. The light source apparatus of the present embodiment generates light, such as illumination light and exposure light, used for an optical apparatus, such as an inspection apparatus and a lithography apparatus. The light source apparatus may be provided integrally with the optical apparatus, or be disposed, as an apparatus separated from the optical apparatus, adjacent to the optical apparatus. In the case where the optical apparatus is an inspection apparatus, the light source apparatus generates illumination light with which an inspection target in the inspection apparatus is illuminated. In the case where the optical apparatus is the lithography apparatus, the light source apparatus generates exposure light with which an exposure target in the lithography apparatus is exposed.

The light source apparatus irradiates a target material held at a target holding unit with excitation light, thereby generating light, such as illumination light and exposure light. In the following first embodiment, as an example of the light source apparatus, an example is described where molten metal held at the target holding unit that includes a container, such as a crucible, is adopted as the target material. In a second embodiment, a light source apparatus that adopts, as the target material, a solid held at a target holding unit, such as a cylindrical drum, is described. Note that the light source apparatus is not limited to what adopts, as the target material, molten metal held in a container, such as a crucible, and what adopts, as the target material, a solid or the like held at the target holding unit, such as a cylindrical drum. Alternatively, the apparatus may be what adopts, as the target material, solid metal or the like held at a tape-shaped target holding unit, or what adopts, as the target material, droplet-shaped liquid metal.

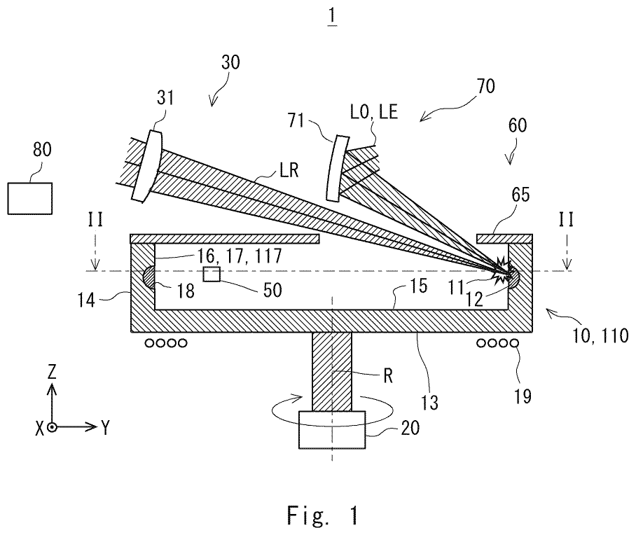

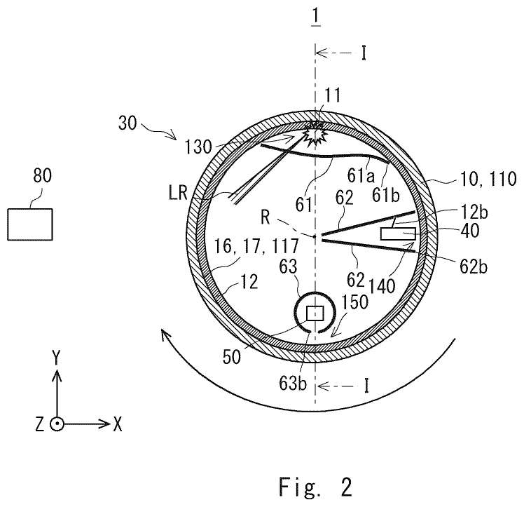

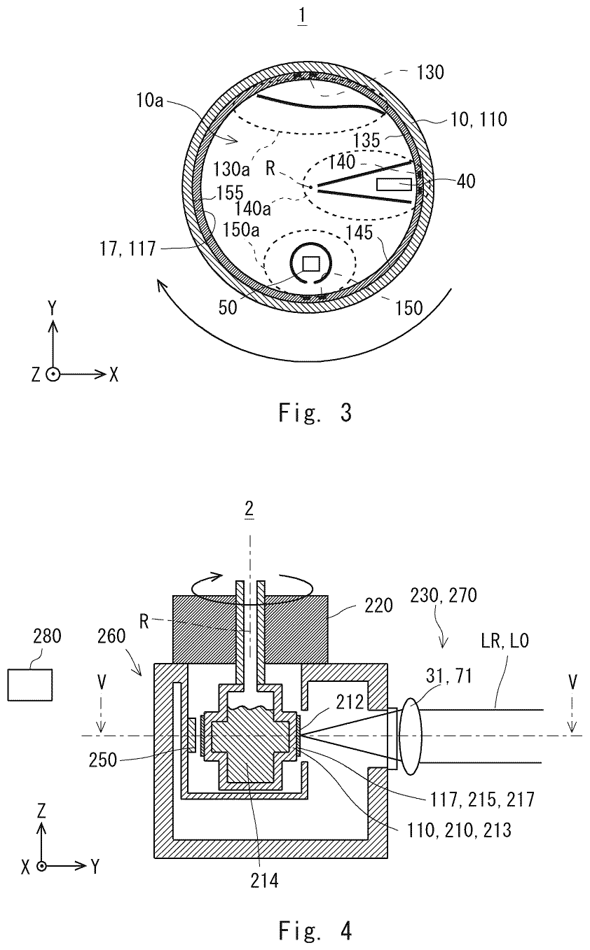

FIG. 1 is a sectional view showing an example of the light source apparatus 1 according to the first embodiment, and shows a section taken along line I-I of FIG. 2. FIG. 2 is a sectional view showing an example of the light source apparatus 1 according to the first embodiment, and shows a section taken along line II-II of FIG. 1. FIG. 3 is a schematic diagram showing an example of an internal space 10a of a target holding unit 10 in the light source apparatus 1 according to the first embodiment. In FIGS. 1 to 3, some of members are sometimes omitted in order to prevent the drawings from being complicated. For example, in FIG. 1, debris shields 61 to 63 of a cover part 60 are omitted.

As shown in FIGS. 1 to 3, the light source apparatus 1 includes the target holding unit 10, and a drive unit 20. Note that the light source apparatus 1 may further include a formation unit 30, a supply unit 40, an observation unit 50, a cover part 60, an output optical system 70, and a control unit 80, in addition to the target holding unit 10 and the drive unit 20.

Here, for the sake of convenience in describing the light source apparatus 1, an XYZ orthogonal coordinate system is introduced. For example, the rotational axis R of the target holding unit 10 is assumed as the Z-axis direction. Note that the introduced XYZ orthogonal coordinate system is for the sake of convenience in description, and does not limit the orientation of each member.

The target holding unit 10 holds a target material 12. The target holding unit 10 may include, for example, a container, such as a crucible. The target holding unit 10 allows metal to melt inside. The target holding unit 10 holds the target material 12, such as molten metal, for generating plasma 11 due to irradiation with excitation light LR. The excitation light LR is laser light that includes, for example, IR (Infrared) light.

Note that as described later, the target holding unit 10 is not limited to what includes a container, such as a crucible. For example, the target holding unit 10 may be a cylindrical (cylinder-shaped) drum. In this case, the target holding unit 10 holds the target material 12 by fixing a substance serving as this target material 12, such as frozen xenon (Xe), on the surface of the drum in a solid state, for example.

The target material 12 is not limited to molten metal held at the target holding unit 10, and may be a substance in a solid state, solid metal, a droplet or the like, as long as it is a substance that generates plasma 11 by irradiation with excitation light LR. The molten metal may be, for example, molten tin (Sn), lithium (Li) or the like, but is not limited to tin, lithium or the like as long as it generates plasma 11 by irradiation with excitation light LR.

The target holding unit 10 has the rotational axis R, and rotates around the rotational axis R centered at the rotational axis R. The rotational axis R may be substantially orthogonal to a contact surface. This applies the centrifugal force uniformly to the target material 12 held at the target holding unit 10. Accordingly, the thickness of the target material 12 can become uniform, which can stabilize light L0 extracted from the light source apparatus 1.

The target holding unit 10 has, for example, a cylindrical shape with one opening being closed. The closed portion of the target holding unit 10 is called a bottom part 13. The cylindrical portion of the target holding unit 10 is called a cylindrical part 14. An inner surface of the bottom part 13 is called a bottom surface 15. The inner surface of the cylindrical part 14 is called an inner wall surface 16. The target holding unit 10 has a holding surface 17 on which the target material 12 is held. For example, the target holding unit 10 has an inner wall surface 16 as the holding surface 17. In this case, the target holding unit 10 holds the target material 12 on the inner wall surface 16 by the centrifugal force. Note that the target holding unit 10 may adopt a surface, such as the bottom surface 15, other than inner wall surface 16, as the holding surface 17, as long as it can hold the target material 12, which contains molten metal or the like. The target holding unit 10 may have a shape other than that described above as long as it can hold the target material 12.

The inner wall surface 16 formed to surround the rotational axis R may have a groove 18 formed along the inner periphery. The groove 18 is formed along, for example, an intersection between the inner wall surface 16 and a surface orthogonal to the rotational axis R. The groove 18 is formed concave in the inner wall surface 16 in a direction away from the rotational axis R. In the case where the inner wall surface 16 has the groove 18, the target material 12 may be held in the groove 18. By holding the target material 12 in the groove 18, the movement of the target material 12 in the Z axis direction can be limited, which can prevent the liquid surface of the target material 12 from being disturbed. Furthermore, the amount of target material 12 can be limited within the groove 18. Accordingly, the required amount of the target material 12 can be reduced. Note that part of the target material 12 may be positioned outside of the groove 18.

Note that the inner wall surface 16 formed to surround the rotational axis R may include a cylindrical portion that has a constant distance from the rotational axis R. The inner wall surface 16 may include an inclined surface that varies in distance from the rotational axis R. For example, the inner wall surface 16 may be provided with a corner radius at a portion connected to the bottom surface 15. As long as the target material 12 can be held, the shape of the inner wall surface 16 is not limited to the groove 18, a cylindrical surface, an inclined surface, what has a corner radius and the like.

The target holding unit 10 is provided with a heater 19. Heating by the heater 19 can form the target material 12, such as molten metal, in the target holding unit 10.

The drive unit 20 is coupled to the target holding unit 10 via a drive transmission mechanism, such as a shaft. The drive unit 20 drives the target holding unit 10 by transmitting the power to the target holding unit 10. The drive unit 20 drives the target holding unit 10, and moves the holding surface 17. For example, the drive unit 20 may transport the target material 12 to the target holding unit 10 by rotating this target holding unit 10 around the rotational axis R. When the target holding unit 10 is viewed from the +Z-axis direction to the −Z axis direction, the drive unit 20 rotates the target holding unit 10 around the rotational axis R in a direction in which the hands of a clock rotate. Note that the drive unit 20 may rotate the target holding unit 10 around the rotational axis R in the direction opposite to the direction in which the hands of a clock rotate.

Here, the predetermined direction where the drive unit 20 rotates the target holding unit 10 around the rotational axis R is called a movement direction. In one example, the direction in which the hands of a clock rotate around the rotational axis R is called the movement direction. As the target holding unit 10 rotates in the movement direction, the holding surface 17 of the target holding unit 10 also rotates around the rotational axis R in the movement direction. Accordingly, the target material 12 also rotates around the rotational axis R in the movement direction. Thus, the target holding unit 10 has the holding surface 17 that transports the target material 12 for generating the plasma 11, to a plasma formation position 130.

As shown in FIG. 3, the target holding unit 10 has an internal space 10a surrounded by the inner wall surface 16. The internal space 10a includes a plasma formation space 130a, a supply space 140a, and an observation space 150a. In the plasma formation space 130a, the formation unit 30 that includes excitation light LR is disposed. In the supply space 140a, the supply unit 40 that supplies the target material 12 to the holding surface 17 is disposed. In the observation space 150a, the observation unit 50 that acquires the state information on the holding surface 17 is disposed.

A space where the target holding unit 10 is disposed is called a movement space 110. The movement space 110 includes a space in which the target holding unit 10 moves. The movement space 110 has a treatment surface 117 along the holding surface 17. The treatment surface 117 may overlap the holding surface 17. The holding surface 17 moves with respect to the treatment surface 117.

The treatment surface 117 may include the plasma formation position 130, the supply position 140, and the observation position 150. The plasma formation position 130 faces the formation unit 30. The plasma formation position 130 includes a region in which the plasma 11 is formed by the formation unit 30. The supply position 140 faces the supply unit 40. The supply position 140 includes a region in which the target material 12 is supplied to the holding surface 17 by the supply unit 40. The observation position 150 faces the observation unit 50. The observation position 150 includes a region in which the state information on the holding surface 17 is acquired by the observation unit 50.

The treatment surface 117 may include a plurality of plasma formation positions 130, a plurality of supply positions 140, and a plurality of observation positions 150. Accordingly, the treatment surface 117 includes at least one plasma formation position 130, at least one supply position 140, and at least one observation position 150.

The plasma formation position 130, the supply position 140, and the observation position 150 are disposed along the treatment surface 117. For example, the plasma formation position 130, the supply position 140, and the observation position 150 are disposed along the treatment surface 117 in the rotational direction around the rotational axis R. When viewed in the movement direction of the holding surface 17 by the drive unit 20, the treatment surface 117 includes the supply position 140 disposed after the plasma formation position 130. Furthermore, the treatment surface 117 includes the observation position 150 disposed after the supply position 140. Accordingly, when viewed in the movement direction of the holding surface 17 by the drive unit 20, the holding surface 17 includes the supply position 140 disposed between the plasma formation position 130 and the observation position 150. In the direction of movement of the holding surface 17 driven by the drive unit 20, the treatment surface 117 includes the supply position 140 disposed after the plasma formation position 130, and further includes the observation position 150 disposed after the supply position 140.

For example, on the XY plane viewed from the +Z axis direction to the −Z axis direction, the position of the treatment surface 117 in a case where the rotational axis R is assumed as the origin is defined by an angle from +Y axis. Thus, the plasma formation position 130 is disposed in a region that includes 0°, for example. The supply position 140 is disposed in a region that includes 90°, for example. The observation position 150 is disposed in a region that includes 180°. Thus, the treatment surface 117 includes the supply position 140 disposed at a position at +90° in the movement direction from the plasma formation position 130. The treatment surface 117 includes the observation position 150 disposed at a position at +90° in the movement direction from the supply position 140.

As described above, provided that the movement direction of the holding surface 17 by the drive unit 20 is defined as a direction (0° to 360°) of increasing the angle from a predetermined radius (for example, +Y axis) with rotational axis R being assumed as the origin, the treatment surface 117 includes the supply position 140 disposed at a position of increasing the angle (in the movement direction) from the plasma formation position 130. The treatment surface 117 includes the observation position 150 disposed at a position of increasing the angle (in the movement direction) from the supply position 140.

By arranging the treatment surface 117 to include the supply position 140 disposed after the plasma formation position 130, the state of the target material 12 supplied at the supply position 140 is made more stable, and then plasma can be formed at the plasma formation position 130. By arranging the treatment surface 117 to include the observation position 150 disposed after the supply position 140, the state information on the holding surface 17 that includes the target material 12 supplied at the supply position 140 can be acquired.

In view of the internal space 10a, the plasma formation space 130a, the supply space 140a, and the observation space 150a are disposed along the treatment surface 117. When viewed in the movement direction of the holding surface 17 by the drive unit 20, the internal space 10a includes the supply space 140a disposed after the plasma formation space 130a. Furthermore, the internal space 10a includes the observation space 150a disposed after the supply space 140a.

When viewed from the movement direction of the holding surface 17 by the drive unit 20, the length from the plasma formation position 130 to the supply position 140 along the treatment surface 117 is shorter than the length from the supply position 140 to the plasma formation position 130 along the treatment surface 117. That is, the length measured from the plasma formation position 130 as the starting point to the supply position 140 along the treatment surface 117 in the direction in which the hands of a clock rotate is shorter than the length measured from the supply position 140 as the starting point to the plasma formation position along the treatment surface 117 in the direction in which the hands of a clock rotate. In the direction of movement of the holding surface 17 driven by the drive unit 20, a length from the plasma formation position 130 to the supply position 140 along the treatment surface 117 is shorter than a length from the supply position 140 to the plasma formation position 130 along the treatment surface 117. By adopting such a configuration, the state of the target material 12 supplied at the supply position 140 is made more stable, and then plasma can be formed at the plasma formation position 130.

When viewed from the movement direction of the holding surface 17 by the drive unit 20, the length from the supply position 140 to the observation position 150 along the treatment surface 117 is shorter than the length from the observation position 150 to the plasma formation position 130 along the treatment surface 117. In the direction of movement of the holding surface 17 driven by the drive unit 20, a length from the supply position 140 to the observation position 150 along the treatment surface 117 is shorter than a length from the observation position 150 to the plasma formation position 130 along the treatment surface 117. According to such a configuration, the observation position 150 can be kept away from the plasma formation position 130, and the state of the holding surface 17 after the target material 12 is supplied can be observed. Consequently, the adverse effect of debris occurring at the plasma formation position 130 on the observation unit 50 can be reduced, and the state information on the holding surface 17, such as the thickness of the target material 12 toward the plasma formation position 130, can be accurately acquired.

Note that it is preferable that the plasma formation position 130 be disposed at a position facing the observation position 150 with respect to the rotational axis R of the target holding unit 10. Accordingly, the adverse effect of debris occurring at the plasma formation position 130 on the observation unit 50 can be further reduced.

In view of the internal space 10a, when viewed in the movement direction of the holding surface 17 by the drive unit 20, the length from the plasma formation space 130a to the supply space 140a along the treatment surface 117 is shorter than the length from the supply space 140a to the plasma formation space 130a along the treatment surface 117. When viewed in the movement direction of the holding surface 17 by the drive unit 20, the length from the supply space 140a to the observation space 150a along the treatment surface 117 is shorter than the length from the observation space 150a to the plasma formation space 130a along the treatment surface 117. Furthermore, it is preferable that the plasma formation space 130a be disposed at a position facing the observation space 150a with respect to the rotational axis R of the target holding unit 10.

The formation unit 30 includes excitation light LR and the like disposed in the plasma formation space 130a. The formation unit 30 focuses laser light LR on the target material 12 at the plasma formation position 130, thereby exciting the target material 12 at the plasma formation position 130. Accordingly, the formation unit 30 generates the plasma 11 from the target material 12. When the plasma 11 is generated, EUV light LE is generated from the plasma 11. For example, the EUV light LE is used as light L0, such as illumination light, in an optical apparatus that is an inspection apparatus, a lithography apparatus or the like.

The formation unit 30 may include the optical member 31. The optical member 31 irradiates the target material 12 with the excitation light LR. The optical member 31 includes, for example, at least any of a mirror and a condenser lens. Note that the optical member 31 is not limited to a mirror or a condenser lens, and may be a laser apparatus that generates the excitation light LR, as long as it irradiates the target material 12 with the excitation light LR.

The light source apparatus 1 may include a laser apparatus or the like that generates the excitation light LR. On the other hand, the light source apparatus 1 may introduce, into the light source apparatus 1, excitation light LR from a laser apparatus installed separately from the light source apparatus 1 outside of the light source apparatus 1. The laser apparatus emits, for example, excitation light LR that includes IR light. The excitation light LR may irradiate the target material 12 under vibration and stopping control by the control unit 80. For example, the excitation light LR is focused by the optical member 31. Thus, the excitation light LR irradiates the target material 12.

The optical member 31 irradiates the target material 12 with the excitation light LR at an angle inclined on a near side with respect to the movement direction of the target holding unit 10, from an axis perpendicular to the surface of the target material 12. Accordingly, the angular velocity in the rotational direction of the target holding unit 10 is added in the debris scattering direction, and debris is allowed to scatter on the opposite side of the direction of reflection of the excitation light LR. Consequently, the amount of debris scattering toward the laser apparatus can be reduced.

The supply unit 40 is disposed in the supply space 140a. The supply unit 40 supplies the target material 12 to the holding surface 17 at the supply position 140. The supply unit 40 may supply a solid target material 12 to the holding surface 17. The solid target material 12 may have a linear shape. The linear target material 12 may be held in a state of being wound around a bobbin or the like. The supply unit 40 supplies the linear target material 12 from the bobbin into the target holding unit 10.

The supply unit 40 may supply the molten target material 12 to the holding surface 17. For example, the supply unit 40 may supply the target material 12 molten using the debris shield 62, to the holding surface 17. The debris shield 62 is disposed adjacent to the supply position 140. The debris shield 62 is disposed to face the supply position 140, for example. The debris shield 62 is exposed to a temperature higher than or equal to the melting point of the target material 12. As described above, the debris shield 62 may be set to a temperature higher than or equal to the melting point of the target material 12, by the radiation heat at the target holding unit 10 and the target material 12 in the target holding unit 10. The debris shield 62 may be adjusted to a temperature higher than or equal to the melting point of the target material 12 by a heating member, such as a heater.

Note that the debris shield 61 disposed to face the plasma formation position 130, and the debris shield 63 disposed to face the observation position 150 may be adjusted to a temperature higher than or equal to the melting point of the target material 12. That is, at least any of the debris shields 61 to 63 may be adjusted to a temperature higher than or equal to the melting point of the target material 12. Accordingly, the target material 12 that has become debris can be reused to generate plasma.

The supply unit 40 may melt a solid target material 12b by making contact with the debris shield 62 or the like, and then be supplied into to the target holding unit 10. For example, the target material 12 melted by the debris shield 62 falls to the bottom surface 15, and subsequently reaches the inner wall surface 16 by the centrifugal force. This negates the need to bring a solid target material 12b into contact with the target material 12 of the holding surface 17. Accordingly, the temperature of the target material 12 of the holding surface 17 can be prevented from decreasing. The disturbance of the surface state of the target material 12 due to vibrations and the like can be prevented.

The observation unit 50 is disposed in the observation space 150a. The observation unit 50 acquires the state information on the holding surface 17 at the observation position 150. The state information on the holding surface 17 may be the surface irregularities, surface roughness, height, reflectance or the like of the target material 12 held on the holding surface 17. Alternatively, the state information on the holding surface 17 may be presence or absence, the sizes or the like of scratches and adhering substances on the holding surface 17. For example, the observation unit 50 acquires the position of the target material 12 held by the holding surface 17 with respect to the holding surface 17. In this case, the observation unit 50 may include a position sensor. The observation unit 50 may include various sensors, such as a temperature sensor and a stress sensor, besides the position sensor. By the position sensor, the observation unit 50 actually measures and acquires the surface position of the target material 12. The position sensor may include, for example, a displacement meter, a high-speed camera, a low-speed camera, a quadrant PD (Photo Diode), or a TDI (Time Delay Integration) camera. The position sensor may be any of what one-dimensionally measures the surface position, what two-dimensionally measures it, and what three-dimensionally measures it, or a combination of some of them.

The observation unit 50 that includes the position sensor and the like acquires the displacement of the surface position of the target material 12, based on the acquired surface position of the target material 12. The observation unit 50 may acquire the surface position of the target material 12, based on the thickness from the holding surface 17.

It is desirable that the observation unit 50 be disposed at a position apart from the plasma formation position 130. For example, the observation unit 50 is disposed at a position opposite to the plasma formation position 130 with respect to the rotational axis R. Thus, the adverse effect of debris can be prevented, and the measurement accuracy at the surface position can be improved.

The cover part 60 includes the debris shields 61 to 63, and a debris cover 65. Note that the cover part 60 does not necessarily include all the debris shields 61 to 63, and the debris cover 65. The cover part 60 may include at least any of the debris shields 61 to 63, and the debris cover 65.

The debris cover 65 is disposed so as to cover the target holding unit 10. For example, the debris cover 65 covers the opening of the target holding unit 10 on the +Z-axis direction side. Note that the debris cover 65 has an opening formed to extract the excitation light LR and the EUV light LE. The debris cover 65 prevents debris scattering at the same time of occurrence of the plasma 11 from adhering to a collector mirror and the like. Note that as described above, the debris cover 65 may be adjusted to a temperature higher than or equal to the melting point of the target material 12.

The debris shield 61 is disposed in the plasma formation space 130a. The debris shield 61 is disposed so as to cover the plasma formation position 130. The debris shield 61 may include a portion disposed to face a region 135 between the plasma formation position 130 and the supply position 140 on the treatment surface 117, and a portion disposed to face a region 155 between the plasma formation position 130 and the observation position 150 on the treatment surface 117. Specifically, the debris shield 61 includes a portion disposed between the formation unit 30 and the supply unit 40, and a portion disposed between the formation unit 30 and the observation unit 50. As described above, the cover part 60 further includes a first debris shield (part of the debris shield 61) disposed to face the region 135 between the plasma formation position 130 and the supply position 140. The cover part 60 further includes a first debris shield (part of the debris shield 61) disposed in the region 135 between the plasma formation position 130 and the supply position 140.

When viewed from the +Z axis direction to the −Z axis direction, the debris shield 61 includes an elongated portion 61a where a distance from the treatment surface 117 decreases in the movement direction. The debris shield 61 includes an elongated portion 61a where a distance from the movement trajectory of the holding surface 17 decreases in the movement direction. For example, a portion of the debris shield 61 on the +X-axis direction side includes the elongated portion 61a that has a decreasing distance from the treatment surface 117. The angle between the elongated portion 61a that is of the debris shield 61 and includes the end part 61b on the movement direction side, and the tangent of the treatment surface 117 on the extended line of the end part 61b is less than 90°. The tangent of the movement trajectory of the holding surface 17 on the extended line of the end part 61b is less than 90°. When viewed from the +Z axis direction to the −Z axis direction, the elongated portion 61a that includes the end part 61b has a convex shape toward the treatment surface 117. Accordingly, the angle from the tangent of the treatment surface 117 on the extended line of the end part 61b decreases as approaching the end part 61b. The portion of the debris shield 61 on the +X-axis direction side portion that includes the end part includes the elongated portion 61a where a distance from the movement trajectory of the holding surface 17 decreases in the movement direction, and has a convex shape on a side closer to the holding surface 17, to reduce an angle from the tangent of the movement trajectory of the holding surface 17 on the extended line of the end part as approaching the end part.

The debris shields 62 are disposed in the supply space 140a. The debris shields 62 are disposed so as to cover the supply position 140. The debris shields 62 are disposed so as to cover the supply unit 40 on both the sides. The debris shields 62 may include a portion disposed to face a region 145 between the supply position 140 and the observation position 150 on the treatment surface 117, and a portion disposed to face the region 135 between the supply position 140 and the plasma formation position 130 on the treatment surface 117. Specifically, the debris shields 62 include a portion disposed between the supply unit 40 and the observation unit 50, and a portion disposed between the supply unit 40 and the formation unit 30. As described above, the cover part 60 further includes a second debris shield (part of the debris shields 62) disposed to face the region 145 between the supply position 140 and the observation position 150. The cover part 60 further includes a second debris shield (part of the debris shields 62) disposed in the region 145 between the supply position 140 and the observation position 150.

The debris shield 62 may include a portion disposed on the line extending from the rotational axis R of the target holding unit 10 to the treatment surface 117. That is, the debris shield 62 may include a moving radius portion. Accordingly, the debris shield 62 can smoothly supply the target material 12 that is molten debris to the holding surface 17 by the centrifugal force.

The portion of the debris shield 62 that includes the end part 62b on the movement direction side may be curved. The angle between the curved portion of the debris shield 62 that includes the end part 62b on the movement direction side, and the tangent of the treatment surface 117 on the extended line of the end part 62b may be less than 90°.

The debris shield 63 is disposed in the observation space 150a. The debris shield 63 is disposed so as to cover the observation position 150. The debris shield 63 is disposed so as to cover the observation unit 50 from both the sides. The debris shield 63 may include a portion disposed to face the region 155 between the observation position 150 and the plasma formation position 130 on the treatment surface 117, and a portion disposed to face the region 145 between the observation position 150 and the supply position 140 on the treatment surface 117. Specifically, the debris shield 63 includes a portion disposed between the observation unit 50 and the formation unit 30, and a portion disposed between the observation unit 50 and the supply unit 40. As described above, the cover part 60 further includes a third debris shield (part of the debris shield 63) disposed to face the region 155 between the plasma formation position 130 and the observation position 150. The cover part 60 further includes a third debris shield (part of the debris shield 63) disposed in the region 155 between the plasma formation position 130 and the observation position 150.

The portion of the debris shield 63 that includes the end part 63b on the movement direction side may be curved. The angle between the curved portion of the debris shield 63 that includes the end part 63b on the movement direction side, and the tangent of the treatment surface 117 on the extended line of the end part 63b may be less than 90°.

The cover part 60 includes the first debris shield, the second debris shield, and the third debris shield that respectively disposed in the region 135 between the plasma formation position 130 and the supply position 140 on the treatment surface 117, the region 145 between the supply position 140 and the observation position 150 on the treatment surface 117, and the region 155 between the plasma formation position 130 and the observation position 150 on the treatment surface 117. Here, the first debris shield includes part of the debris shield 61 or part of the debris shield 62. The second debris shield includes part of the debris shield 62 or part of the debris shield 63. The third debris shield includes part of the debris shield 63 or part of the debris shield 61.

At least any of the first debris shield, the second debris shield, and the third debris shield may be attached to the debris cover 65.

The cover part 60 may include a plurality of first debris shields, a plurality of second debris shields, and a plurality of third debris shields that are respectively disposed in the region 135 between the plasma formation position 130 and the supply position 140 on the treatment surface 117, the region 145 between the supply position 140 and the observation position 150 on the treatment surface 117, and the region 155 between the plasma formation position 130 and the observation position 150 on the treatment surface 117. Here, a plurality of first debris shields include part of the debris shield 61 and part of the debris shield 62. A plurality of second debris shields include part of the debris shield 62 and part of the debris shield 63. A plurality of third debris shields include part of the debris shield 63 and part of the debris shield 61.

The output optical system 70 extracts the light L0 generated by irradiating the target material 12 with the excitation light LR, from the light source apparatus 1. The output optical system 70 includes, for example, an optical member 71. The optical member 71 includes, for example, a collector mirror. Note that the optical member 71 is not limited to the collector mirror, and may be a second collector mirror (not shown) that further reflects the light L0 reflected by the collector mirror, as long as it is an optical member that extracts the light L0 generated by irradiating the target material 12 with the excitation light LR.

The optical member 71 reflects the light L0 generated from the target material 12 by irradiation with the excitation light LR. The optical member 71 reflects, for example, EUV light LE generated by irradiation with the excitation light LR. That is, the light L0 may include EUV light LE. The EUV light LE is generated from the plasma 11 generated by irradiating the target material 12 with the excitation light LR. The EUV light LE generated from the plasma 11 occurring at the target material 12 is emitted, as illumination light, to an optical apparatus, such as an inspection apparatus. Consequently, the illumination light includes the EUV light LE generated from the plasma 11.

The control unit 80 may control each member of the light source apparatus 1. The control unit 80 is connected to each member of the light source apparatus 1 via communication lines including wireless and wired ones in a state capable of transmitting information. The control unit 80 analyzes, for example, the state information on the target material 12 acquired by the observation unit 50. The control unit 80 analyzes output information that includes the intensity, irradiation position and the like of the light L0, such as illumination light, output by the output optical system 70.

The control unit 80 controls the formation state of plasma that includes the intensity, irradiation position and the like of the excitation light LR at the formation unit 30, based on the state information on the target material 12, on the output information on the light L0, such as illumination light, and the like. The control unit 80 controls the supply state that includes the temperature, amount of supply and the like of the target material 12 at the supply unit 40, based on the state information, the output information and the like. The control unit 80 controls the temperature and the like of the cover part 60, based on the state information, the output information and the like.

Next, the advantageous effects of the present embodiment are described. In the light source apparatus 1 of the present embodiment, the plasma formation position 130, the supply position 140, and the observation position 150 are disposed along the treatment surface 117. In view in the movement direction, the treatment surface 117 includes the supply position 140 disposed after the plasma formation position 130, and the observation position 150 disposed after the supply position 140. Consequently, the state of the target material 12 supplied at the supply position 140 is made more stable, and then plasma can be formed at the plasma formation position 130. The state information on the holding surface 17 where the target material 12 supplied at the supply position 140 is included can be acquired. Furthermore, at the plasma formation position 130, the effect on the surface state due to the supply of the target material 12 during generation of the plasma 11 can be reduced. The state information, such as on the thickness or the like of the target material 12, at the plasma formation position 130 can be accurately acquired.

In the light source apparatus 1, the length from the plasma formation position 130 to the supply position 140 along the treatment surface 117 is shorter than the length from the supply position 140 to the plasma formation position 130 along the treatment surface 117. Thus, the state of the target material 12 supplied at the supply position 140 is made more stable, and then plasma is formed at the plasma formation position 130. Such a configuration can also reduce the effects on the surface state due to the supply of the target material 12.

In the light source apparatus 1, the length from the supply position 140 to the observation position 150 along the treatment surface 117 is shorter than the length from the observation position 150 to the plasma formation position 130 along the treatment surface 117. Consequently, the adverse effect of debris occurring at the plasma formation position 130 on the observation unit 50 can be further reduced.

### Second Embodiment

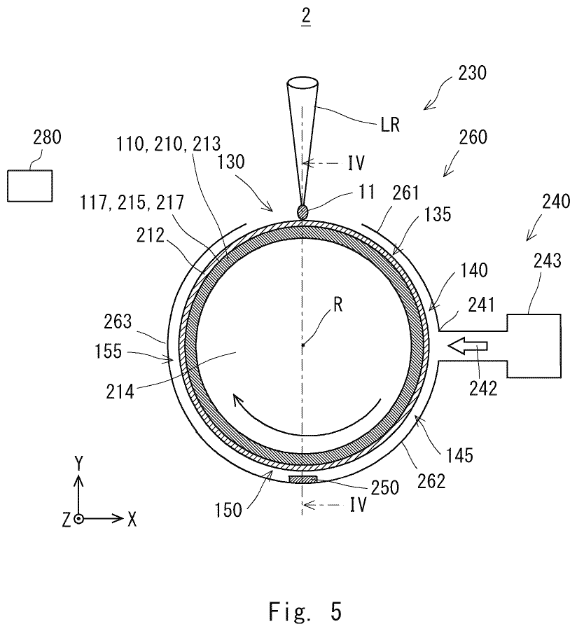

Next, a light source apparatus 2 of a second embodiment is described. FIG. 4 is a sectional view showing an example of the light source apparatus 2 according to the second embodiment, and shows a section taken along line IV-IV of FIG. 5. FIG. 5 is a sectional view showing an example of the light source apparatus 2 according to the second embodiment, and shows a section taken along line V-V of FIG. 4. As shown in FIGS. 4 and 5, the light source apparatus 2 includes a target holding unit 210, and a drive unit 220. Note that the light source apparatus 2 may further include a formation unit 230, a supply unit 240, an observation unit 250, a cover part 260, an output optical system 270, and a control unit 280, in addition to the target holding unit 210 and the drive unit 220.

The target holding unit 210 holds a target material 212. The target holding unit 210 includes a cylindrical (cylinder-shaped) drum 213. The inside of the drum 213 is filled with coolant 214, such as liquid nitrogen. The target holding unit 210 holds the target material 212 by fixing a solid serving as the target material 212, such as frozen xenon (Xe), on an outer periphery 215 of the drum 213. In the present embodiment, a holding surface 217 of the target holding unit 210 includes the outer periphery 215 of the drum 213.

The drive unit 220 drives the target holding unit 210, and moves the holding surface 217. The target holding unit 210 has a rotational axis R. When the target holding unit 210 is viewed from the +Z-axis direction to the −Z axis direction, the drive unit 220 rotates the target holding unit 210 around the rotational axis R in a direction in which the hands of a clock rotate.

The formation unit 230 is disposed on the +Y-axis direction side of the target holding unit 210. The formation unit 230 irradiates the target material 212 held on the holding surface 217 of the target holding unit 210 in the +Y-axis direction side with excitation light LR traveling in the −Y-axis direction. Consequently, the plasma formation position 130 includes a portion of the holding surface 217 on the +Y-axis direction side.

The supply unit 240 is disposed on the +X-axis direction side of the target holding unit 210. The supply unit 240 has a supply port 241. The supply port 241 faces the +X-axis direction side of the target holding unit 210. Consequently, the supply position 140 includes a portion of the holding surface 217 on the +X-axis direction side. The supply port 241 communicates with a supply source 243 of gas 242 of the target material 212. The supply source 243 supplies the gas 242 of the target material 212 to the supply position 140 through the supply port 241. The gas 242 of the target material 212 supplied through the supply port 241 is fixed on the surface of the drum 213, thereby forming the target material 212.

The observation unit 250 is disposed on the −Y-axis direction side of the target holding unit 210. Consequently, the observation position 150 includes a portion of the holding surface 217 on the −Y-axis direction side.

In the present embodiment, in the movement space 110, the target holding unit 210 is disposed. The target holding unit 210 moves in the movement space 110. The movement space 110 has a treatment surface 117 along the holding surface 217. The treatment surface 117 may overlap the holding surface 217. The holding surface 217 moves with respect to the treatment surface 117.

The plasma formation position 130, the supply position 140 and the observation position 150 are disposed along the treatment surface 117. When viewed in the movement direction of the holding surface 217 by the drive unit 220, the treatment surface 117 includes the supply position 140 disposed after the plasma formation position 130. Furthermore, the treatment surface 117 includes the observation position 150 disposed after the supply position 140.

When viewed from the movement direction of the holding surface 217 by the drive unit 220, the length from the plasma formation position to the supply position 140 along the treatment surface 117 is shorter than the length from the supply position 140 to the plasma formation position 130 along the treatment surface 117. Furthermore, the length from the supply position 140 to the observation position 150 along the treatment surface 117 is shorter than the length from the observation position 150 to the plasma formation position 130 along the treatment surface 117.

The cover part 260 includes debris shields 261 to 263. The debris shield 261 is disposed so as to face the region 135 between the plasma formation position 130 and the supply position 140. The debris shield 262 is disposed so as to face the region 145 between the supply position 140 and the observation position 150. The debris shield 263 is disposed so as to face the region 155 between the plasma formation position 130 and the observation position 150.

Also, in the case where the solid or the like held by the target holding unit 210, such as the cylindrical drum, is adopted as the target material 212 as in the present embodiment, advantageous effects can be achieved in a manner similar to that of the first embodiment. That is, the state of the target material 212 supplied at the supply position 140 is made more stable, and then plasma can be formed by the plasma formation position 130. The state information on the holding surface 217 where the target material 212 supplied at the supply position 140 is included can be acquired.

### Modification Example

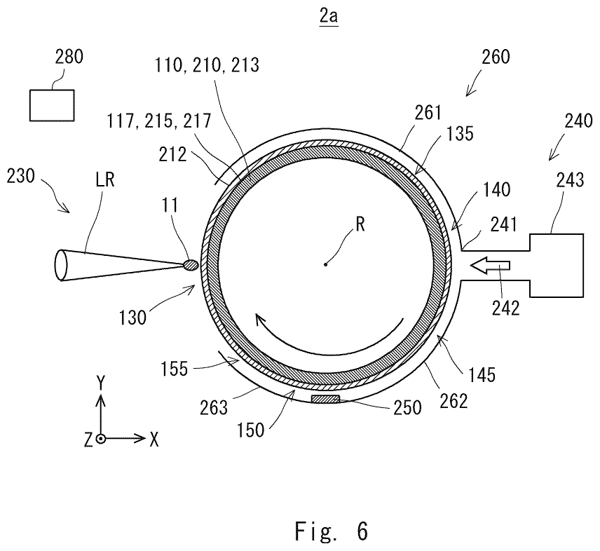

FIG. 6 is a sectional view showing an example of a light source apparatus 2a according to a modification example of the second embodiment. As shown in FIG. 6, in the present modification example, the position of the formation unit 230 is different from that of the light source apparatus 2 of the second embodiment. That is, the formation unit 230 is disposed on the −X-axis direction side of the target holding unit 210. The formation unit 230 irradiates the target material 212 held on the holding surface 217 of the target holding unit 210 on the −X-axis direction side with excitation light LR traveling in the +X-axis direction. Consequently, the plasma formation position 130 includes a portion of the treatment surface 117 on the −X-axis direction side.

Also, according to such a configuration, the plasma formation position 130, the supply position 140, and the observation position 150 are disposed along the treatment surface 117. When viewed in the movement direction of the holding surface 217 by the drive unit 220, the treatment surface 117 includes the supply position 140 disposed after the plasma formation position 130. Furthermore, the treatment surface 117 includes the observation position 150 disposed after the supply position 140. The configuration and components, and advantageous effects other than those are included in the description of the first and second embodiments.

The embodiments of the present disclosure have thus been described above. However, the present disclosure encompasses appropriate modifications without impairing the object and advantages. Furthermore, the present disclosure is not limited by the embodiments described above. The configurations and components of the first and second embodiments, and the modification example may be combined with each other as appropriate.

The first and second embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A light source apparatus, comprising:
a target holding unit that has a holding surface for transporting a target material for generating plasma to at least one plasma formation position; and
a drive unit that drives the target holding unit, and moves the holding surface, wherein:
the holding surface moves with respect to a treatment surface in a space along the holding surface,
the treatment surface includes:
the at least one plasma formation position;
at least one supply position at which the target material is supplied to the holding surface; and
at least one observation position at which state information on the holding surface is acquired,
the plasma formation position, the supply position, and the observation position are disposed along the treatment surface, and
in the direction of movement of the holding surface driven by the drive unit, the treatment surface:
includes the supply position disposed after the plasma formation position, and
further includes the observation position disposed after the supply position.

2. A light source apparatus, comprising:
a target holding unit that has a holding surface for transporting a target material for generating plasma to at least one plasma formation position; and
a drive unit that drives the target holding unit, and moves the holding surface, wherein:
the holding surface moves with respect to a treatment surface in a space along the holding surface,
the treatment surface includes:
the at least one plasma formation position; and
at least one supply position at which the target material is supplied to the holding surface,
the plasma formation position and the supply position are disposed along the treatment surface, and
in the direction of movement of the holding surface driven by the drive unit, a length from the plasma formation position to the supply position along the treatment surface is shorter than a length from the supply position to the plasma formation position along the treatment surface.

3. The light source apparatus according to claim 1, further comprising a formation unit that excites the target material at the plasma formation position by focusing laser light on the target material.

4. The light source apparatus according to claim 1, wherein:
the target holding unit has a rotational axis, and
the drive unit transports the target material to the target holding unit by rotating the target holding unit around the rotational axis.

5. The light source apparatus according to claim 4, wherein the rotational axis is substantially orthogonal to a contact surface.

6. The light source apparatus according to claim 2, wherein:
the treatment surface further includes at least one observation position at which state information on the holding surface is acquired, and
the plasma formation position, the supply position, and the observation position are disposed along the treatment surface.

7. The light source apparatus according to claim 1, wherein in the direction of movement of the holding surface driven by the drive unit, a length from the supply position to the observation position along the treatment surface is shorter than a length from the observation position to the plasma formation position along the treatment surface.

8. The light source apparatus according to claim 1, further comprising a first debris shield disposed in a region between the plasma formation position and the supply position.

9. The light source apparatus according to claim 1, further comprising a second debris shield disposed in a region between the supply position and the observation position.

10. The light source apparatus according to claim 1, further comprising a third debris shield disposed in a region between the plasma formation position and the observation position.

11. The light source apparatus according to claim 1, further comprising a first debris shield, a second debris shield, and a third debris shield that are respectively disposed in a first region between the plasma formation position and the supply position, a second region between the supply position and the observation position, and a third region between the plasma formation position and the observation position.

12. The light source apparatus according to claim 1, further comprising a plurality of first debris shields, a plurality of second debris shields, and a plurality of third debris shields that are respectively disposed in a first region between the plasma formation position and the supply position, a second region between the supply position and the observation position, and a third region between the plasma formation position and the observation position.

13. The light source apparatus according to claim 8, wherein the first debris shield includes an elongated portion where a distance from the movement trajectory of the holding surface decreases in the movement direction.

14. The light source apparatus according to claim 11, wherein an angle between a portion that includes an end part of at least any of the first debris shield, the second debris shield, and the third debris shield on a side in the movement direction, and a tangent of the movement trajectory of the holding surface on an extended line of the end part is less than 90°.

15. The light source apparatus according to claim 14, wherein the portion that includes the end part:
includes an elongated portion where a distance from the movement trajectory of the holding surface decreases in the movement direction, and
has a convex shape on a side closer to the holding surface, to reduce an angle from the tangent of the movement trajectory of the holding surface on the extended line of the end part as approaching the end part.

16. The light source apparatus according to claim 9, wherein the second debris shield includes a portion disposed on a line extending from the rotational axis of the target holding unit to the treatment surface.

17. The light source apparatus according to claim 11, wherein at least any of the first debris shield, the second debris shield, and the third debris shield is attached to a debris cover that covers the target holding unit.

18. The light source apparatus according to claim 11, wherein at least any of the first debris shield, the second debris shield, and the third debris shield is adjusted to have a melting point higher than or equal to that of the target material.

19. The light source apparatus according to claim 1, wherein the plasma formation position is disposed at a position that faces the observation position with respect to the rotational axis of the target holding unit.
